(19) United States
(12) Patent Application Publication
(10) Pub. No.: US 2015/0228919 A1
(43) Pub. Date: Aug. 13, 2015

(54) ORGANIC PHOTOVOLTAIC CELL AND METHOD FOR MANUFACTURING THE SAME

(71) Applicant: KABUSHIKI KAISHA TOSHIBA, Tokyo (JP)

(72) Inventors: Mitsunaga SAITO, Inzai-shi (JP); Masahiro HOSOYA, Okegawa-shi (JP); Michihiko INABA, Yokohama-shi (JP)

(21) Appl. No.: 14/695,997

(22) Filed: Apr. 24, 2015

Related U.S. Application Data
(63) Continuation of application No. 13/046,190, filed on Mar. 11, 2011.

(30) Foreign Application Priority Data
Mar. 11, 2010 (JP) 2010-053950

(51) Int. Cl. H01L 51/44

(52) U.S. Cl. CPC H01L 51/44; H01L 51/441

(57) ABSTRACT

According to one embodiment, there is provided an organic photovoltaic cell including substrate having a plurality of inclined surfaces and a plurality of solar cells formed on the inclined surfaces of the substrate. Each of the solar cells includes a pair of electrodes and a bulk heterojunction active layer interposed between the electrodes, the active layer containing a p-type organic semiconductor and an n-type organic semiconductor. An inclination of each of the inclined surfaces of the substrate against the horizontal plane is in the range of 60 to 89°, and the active layer exhibits a transmission of light within visible wavelength range of 3% or greater.

### CROSS-REFERENCE TO RELATED APPLICATIONS

This application is a continuation of U.S. application Ser. No. 13/046,190 filed Mar. 11, 2011, which is based upon and claims the benefit of priority from prior Japanese Patent Application No. 2010-053950, filed Mar. 11, 2010, the entire contents of both of which are incorporated herein by reference.

### FIELD

Embodiments described herein relate generally to an organic photovoltaic cell (OPVC) and a method for manufacturing the same.

### BACKGROUND

The organic photovoltaic cell is a solar cell utilizing an organic thin-film semiconductor based on a combination of a conductive polymer, fullerene, etc. The organic photovoltaic cell is advantageous in that as compared with a solar cell based on an inorganic material, such as silicon, CIGS or CdTe, it can be manufactured through an easy process, thereby realizing low cost. However, the organic photovoltaic cell has the drawback that the power conversion efficiency (PCE) and operating life of the organic photovoltaic cell are inferior to those of conventional inorganic solar cells. The cause of the drawback is that there are a multiplicity of parameters whose control is difficult, such as semiconductor material purity, molecular weight distribution and orientation, with respect to the organic semiconductor for use in the organic photovoltaic cell.

Various elaborations for enhancing the power conversion efficiency of the organic photovoltaic cell have been made. For example, a mode of installing a multilayered organic photovoltaic cell in inclined form was proposed. Further, an organic photovoltaic cell characterized in that in a active layer, the electric conductor was provided in a projecting form was proposed. This proposal aims at efficiently taking out electrons and holes occurring from a side of the projecting body upon light irradiation. Still further, an organic photovoltaic cell characterized in that the substrate or electrodes had a minute rugged structure was proposed.

### BRIEF DESCRIPTION OF THE DRAWINGS

FIG. 1 is a cross-sectional view of the organic photovoltaic cell according to the first embodiment.

FIG. 2 is a cross-sectional view of a modified form of the first embodiment.

FIG. 3 is a cross-sectional view of the organic photovoltaic cell according to the second embodiment.

FIG. 4 is a cross-sectional view of the organic photovoltaic cell according to the third embodiment.

FIG. 5 is a view of a modified form of the third embodiment.

FIGS. 6A and 6B are cross-sectional views and perspective view of the organic photovoltaic cell according to the fourth embodiment.

FIG. 7 is a view of a modified form of the fourth embodiment.

FIG. 8 is a cross-sectional view of the organic photovoltaic cell according to the fifth embodiment.

FIG. 9 is a view of a modified form of the fifth embodiment.

FIGS. 10A, 10B and 10C are cross-sectional views of the organic photovoltaic cell according to the sixth embodiment.

FIG. 11 is a cross-sectional view of the organic photovoltaic cell according to the seventh embodiment.

FIG. 12 is a flow chart showing an example of the method for manufacturing organic photovoltaic cells according to the embodiments.

FIG. 13 is a view explaining the operation of coating.

FIGS. 14A, 14B, 14C and 14D are views showing an example of module manufacturing process.

FIG. 15 is a view explaining the mechanism of the behavior of a bulk heterojunction solar cell.

FIG. 16 is a view showing the current-voltage characteristics of an inclined cell and a horizontal cell.

FIG. 17 is a view showing the relationship between cell angle θ and power conversion efficiency.

FIG. 18 is a view showing the light path inside a V-shaped cell.

FIG. 19 is a view showing calculation results for the power conversion efficiency distribution inside a V-shaped cell.

FIG. 20 is a view showing changes of sunlight incidence angle of a day.

FIG. 21 is a view showing results of solar radiation intensity measurements of a day in summertime.

FIG. 22 is a view showing changes of electrical energy output per day in accordance with cell angles.

### DETAILED DESCRIPTION

In general, according to one embodiment, there is provided an organic photovoltaic cell including substrate having a plurality of inclined surfaces and a plurality of solar cells formed on the inclined surfaces of the substrate. Each of the solar cells includes a pair of electrodes and a bulk heterojunction active layer interposed between the electrode, the active layer containing a p-type organic semiconductor and an n-type organic semiconductor. An inclination of each of the inclined surfaces of the substrate against the horizontal plane is in the range of 60 to 89°, and the active layer exhibits a transmission of light within visible wavelength range of 3% or greater.

Embodiments of the present invention are explained below in reference to the drawings.

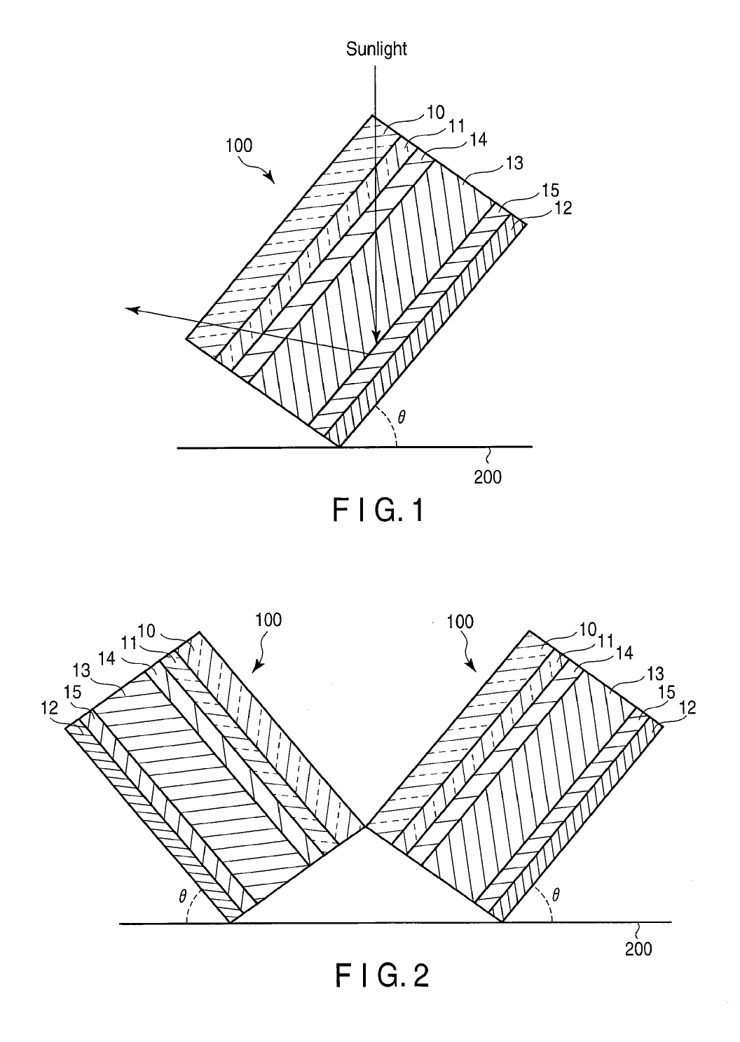

FIG. 1 is a cross-sectional view of the organic photovoltaic cell according to the first embodiment.

A solar cell 100 includes a pair of electrodes (positive electrode 11 and negative electrode 12) which are arranged apart from each other and, interposed between the electrodes 11, 12, a active layer 13, these disposed on a substrate 10. Optionally, a hole transport layer 14 may be interposed between the positive electrode 11 and the active layer 13, and an electron transport layer 15 may be interposed between the negative electrode 12 and the active layer 13.

In the organic photovoltaic cell of this embodiment, the solar cell 100 is set with an inclination of angle θ against the horizontal plane 200. The method for fixing the cell is not shown. The fixing can be effected by, for example, using a support or packing interspaces with a filler. Inclining the solar cell extends the light path for passage of light through the active layer, thereby increasing the efficiency of photon absorption. In this case, it is not necessary to increase the thickness of the active layer for the purpose of the extension of the light path. Therefore, the amount of generated exciton is increased by the extension of the light path, thereby increasing an electric current. Moreover, the film thickness is held small to thereby avoid any increase of film resistance, so that generated carriers without being deactivated can be efficiently transported to the electrodes. As a result, a solar cell realizing an enhanced power conversion efficiency can be obtained.

Further, the organic photovoltaic cell of this embodiment is of a bulk heterojunction type. The characteristic of the bulk heterojunction active layer is that a p-type semiconductor and an n-type semiconductor are blended together to thereby cause a nano-order pn junction to spread over the entirety of the active layer. Accordingly, the pn junction regions are larger in the bulk heterojunction type than in the conventional multilayered type, and the regions actually contributing to power generation spread over the entirety of the active layer in the bulk heterojunction type. Therefore, the regions contributing to power generation of the bulk heterojunction organic photovoltaic cell acquire overwhelming thickness as compared with that of the multilayered organic photovoltaic cell, thereby enhancing the efficiency of photon absorption and increasing the amount of electric current taken out.

Referring to FIG. 2, a pair of solar cells inclined by an angle θ to the horizontal plane may be disposed face-to-face, thereby constituting a V-shaped arrangement. By disposing the cells face-to-face, light reflected on the surface of the cells can be trapped in the cells by a light collecting effect. As a result, the amount of light utilized is increased, thereby enhancing the power conversion efficiency.

The inclination angle θ of the solar cell is in the range of 60 to 89°, preferably 65 to 75°. When the angle θ is 60° or greater, the length of light path is satisfactorily large, so that an improvement of power conversion efficiency is seen. However, when the angle θ exceeds 89°, the area of the whole solar cell becomes excessively large, thereby causing a cost increase.

The light transmission through the active layer 13 is 3% or greater, preferably 10% or greater. When the transmission is less than 3%, any improvement of power conversion efficiency cannot be seen even if the inclination angle of the solar cell is raised. When the transmission is 3% or greater, the power conversion efficiency is increased in accordance with the rise of the inclination angle of the solar cell. In the event of using a material of 100% photoabsorption efficiency, satisfactory photon absorption can be effected regardless of a horizontal arrangement or an inclined arrangement. Thus, the effects of the embodiment of the present invention cannot be recognized. However, the photoabsorption efficiencies of now available organic semiconductors are about several tens of percents (when the film thickness is about 100 nm). Therefore, photons utterly transmitting when the solar cell is horizontally disposed can be absorbed by disposing the solar cell with an inclination so as to extend the length of light path.

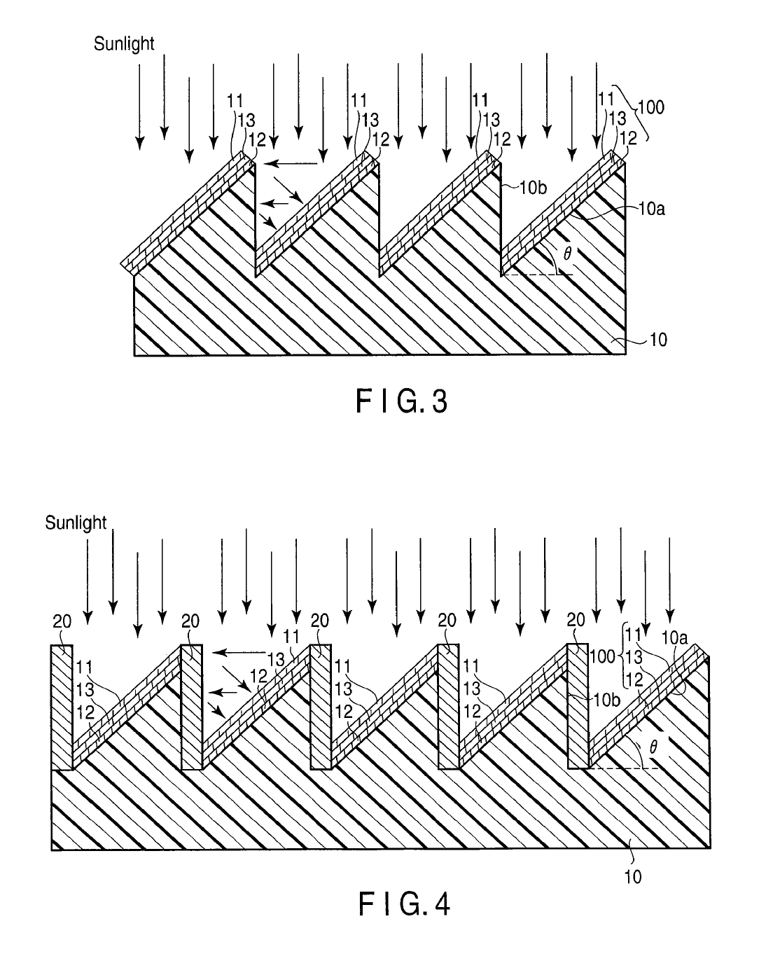

FIG. 3 is a cross-sectional view of the organic photovoltaic cell according to the second embodiment. This organic photovoltaic cell according to the second embodiment is one in which a solar cell 100 is formed on the inclined surfaces 10a of a substrate 10 provided with a plurality of inclined surfaces 10a in parallel and provided with vertical surfaces 10b to the horizontal plane adjacent to the inclined surfaces 10a. The solar cell 100 is formed by disposing a active layer 13 on a negative electrode 12 of vapor deposited aluminum and further providing a transparent positive electrode 11 by sputtering or coating. Although not shown in the figure, a hole transport layer containing PEDOT/PSS or the like and an electron transport layer containing TiOx or the like may be interposed as interlayers.

FIG. 4 is a cross-sectional view of the organic photovoltaic cell according to the third embodiment. The organic photovoltaic cell shown in FIG. 4 is one in which light reflectors 20 are provided on the vertical surfaces 10b adjacent to the inclined surfaces 10a in the organic photovoltaic cell mentioned above in the second embodiment. In this embodiment, the light reflectors 20 are disposed perpendicularly to the horizontal plane. The light reflectors 20 reflect light, so that light is trapped to thereby increase the amount of light that can be utilized. As a result, the power conversion efficiency can be enhanced.

The light reflectors 20 are formed of a material having a surface of high reflectance. For example, use can be made of a metal, such as aluminum or chromium, with a highly polished surface; a mirror-finished light reflector obtained by providing a surface of glass, resin or the like with a reflection coating through, for example, silver plating; a light reflector obtained by carrying out an aluminum vapor deposition on a surface of glass, resin or the like; various metal foils, and the like. In particular, a light reflector exhibiting a reflectance of 98% or higher can be manufactured by using, for example, a reflector film Vikuiti ESR (trade name) produced by 3M Company or the like.

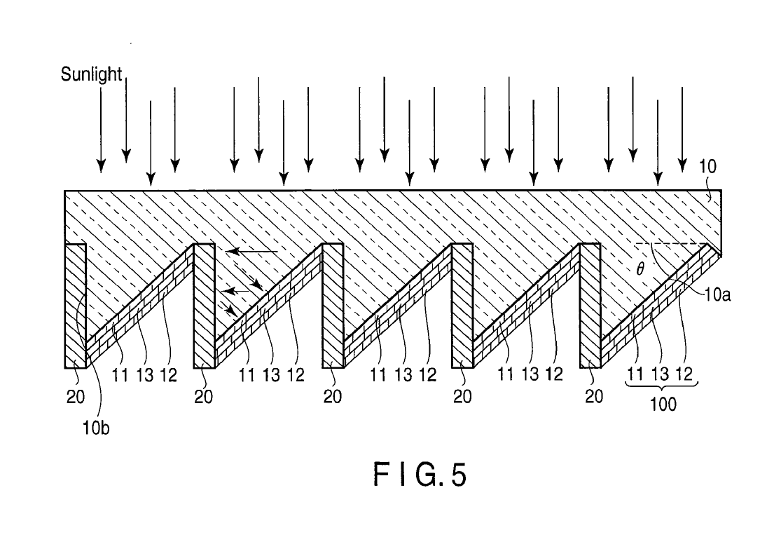

FIG. 5 is a view of a modified form of the third embodiment. Referring to FIG. 5, the substrate 10 may be formed of a transparent material, such as a glass or a resin, and the side of the substrate 10 may be irradiated with light. The solar cell 100 is fabricated by forming a transparent film of positive electrode 11 on each of saw-edged inclined surfaces 10a by sputtering or coating, subsequently providing a active layer 13 and thereafter carrying out aluminum vapor deposition to thereby provide a negative electrode 12. Although not shown in the figure, a hole transport layer containing PEDOT/PSS or the like and an electron transport layer containing TiOx or the like may be interposed as interlayers.

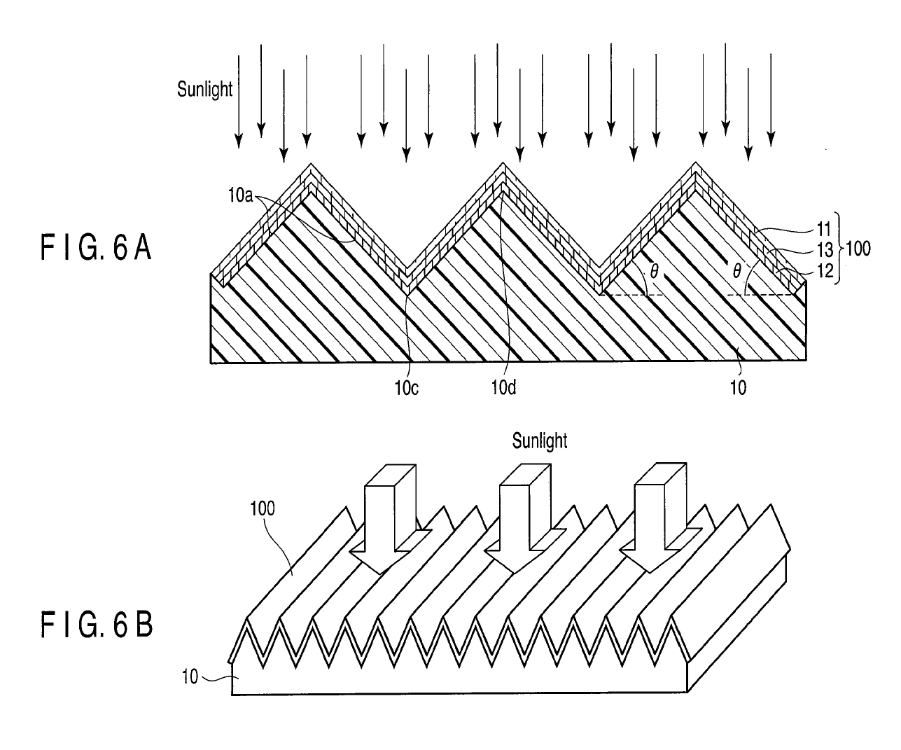

FIG. 6A is a cross-sectional view of the organic photovoltaic cell according to the fourth embodiment. FIG. 6B is a perspective view of the organic photovoltaic cell according to the fourth embodiment. In the organic photovoltaic cell shown in FIG. 6, the substrate 10 is provided with a plurality of inclined surfaces 10a alternately inclined in opposite directions (inclination angle θ against the horizontal plane). A solar cell 100 is formed on the inclined surfaces 10a of the substrate 10.

This organic photovoltaic cell according to the fourth embodiment, as to be described later herein, is obtained by bending a flexible substrate into concertinas and forming a solar cell on the resultant inclined surfaces.

In this structure, the area of the solar cell is larger than in the second embodiment. Thus, a higher power conversion efficiency can be attained.

Referring to FIG. 6A, the height from groove portion 10c to top portion 10d of a concertina structure composed of a plurality of inclined surfaces 10a provided in the substrate 10 is in the range of 1 mm to 20 cm, preferably 3 mm to 10 cm. When the height is extremely large, the device becomes extremely thick, thereby causing the problem that the handling thereof is extremely inconvenient and that the location for installing the device is limited. On the other hand, when the height is extremely small, the region of substantive behavior as a solar cell is so narrow taking the bend margin and coating margin required for the groove portion 10c and top portion 10d into account that a drop of conversion efficiency is caused. This also applies to a case in which a solar cell is formed on a substrate provided with a concertina structure in advance by coating or the like. In a solar cell including a active layer interposed between two electrodes, namely, a positive electrode and an negative electrode, such as the organic photovoltaic cell, it might occur that the two electrodes are short circuited by a deformation attributed to bending. Therefore, it is needed not to form at least one electrode in the area of about 0.2 to 0.5 mm on both sides of each bend line. Further, in the application of a active layer, a liquid puddle is likely to occur in the groove portion. Around the top portion, the thickness of the active layer is likely to be very small. Therefore, in the area of about 0.2 to 0.5 mm on both sides of each of the groove and top portions, satisfactory photoelectric conversion cannot be conducted.

The structure composed of a plurality of slopes with an arbitrary form, including the above-mentioned cell of concertina structure composed of a plurality of triangular waves, is referred to as a multislope structure. For example, the same effects as mentioned above can be obtained by using a multislope cell of sine curve form.

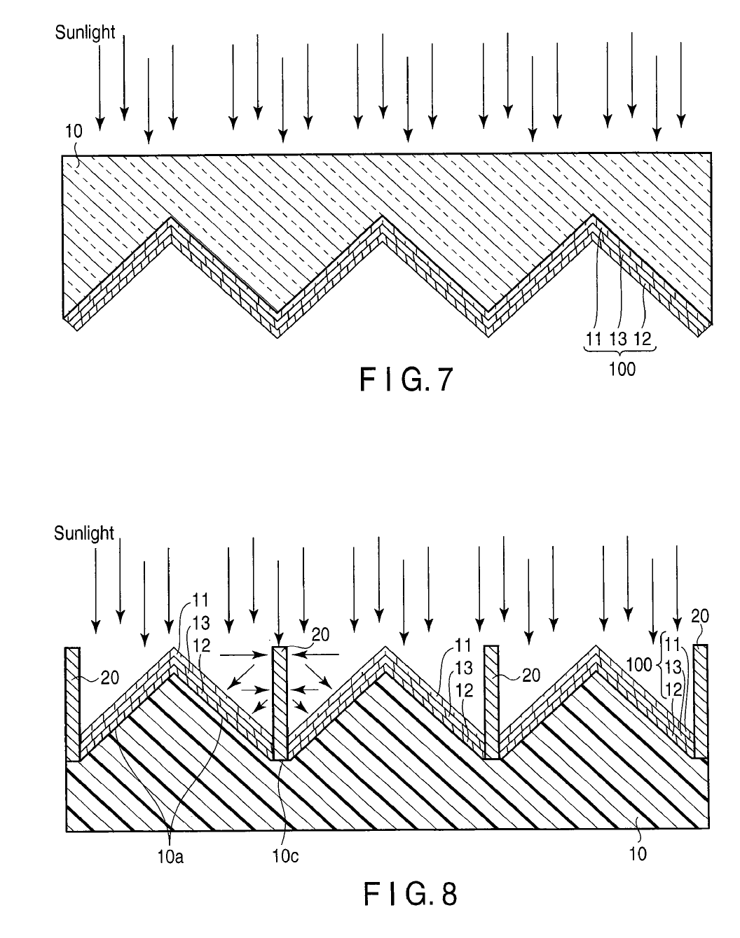

In this embodiment as well, as shown in FIG. 7, the substrate 10 may be formed of a transparent material, and the side of the substrate may be irradiated with light.

FIG. 8 is a cross-sectional view of the organic photovoltaic cell according to the fifth embodiment. The organic photovoltaic cell of FIG. 8 is one in which a light reflector 20 is vertically erected in each groove portion 10c at which two inclined surfaces 10a meet each other in the above organic photovoltaic cell according to the fourth embodiment. The light reflectors 20 are disposed perpendicularly to the horizontal plane. The light reflectors reflect light, so that light is trapped to thereby increase the amount of light that can be utilized. As a result, the power conversion efficiency can be enhanced.

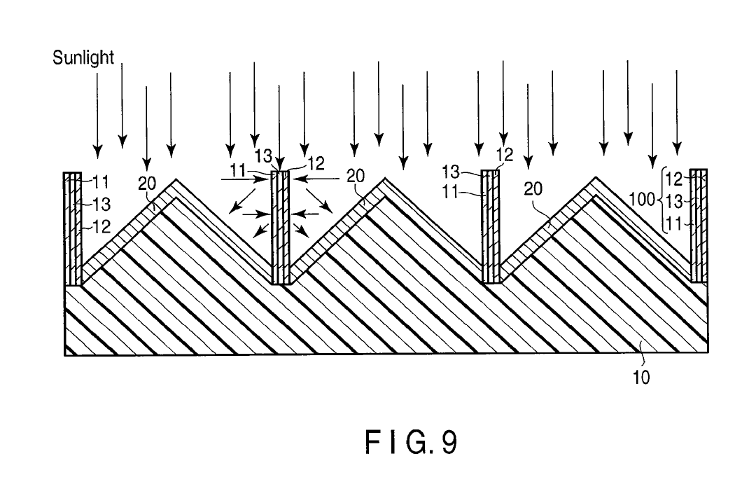

FIG. 9 is a view of a modified form of the fifth embodiment. As shown in FIG. 9, in the fifth embodiment, the locations of light reflector 20 and solar cell 100 may be interchanged. In this arrangement, as a planar solar cell can be cut before use, there can be brought about the advantages of easy fabrication and cost reduction.

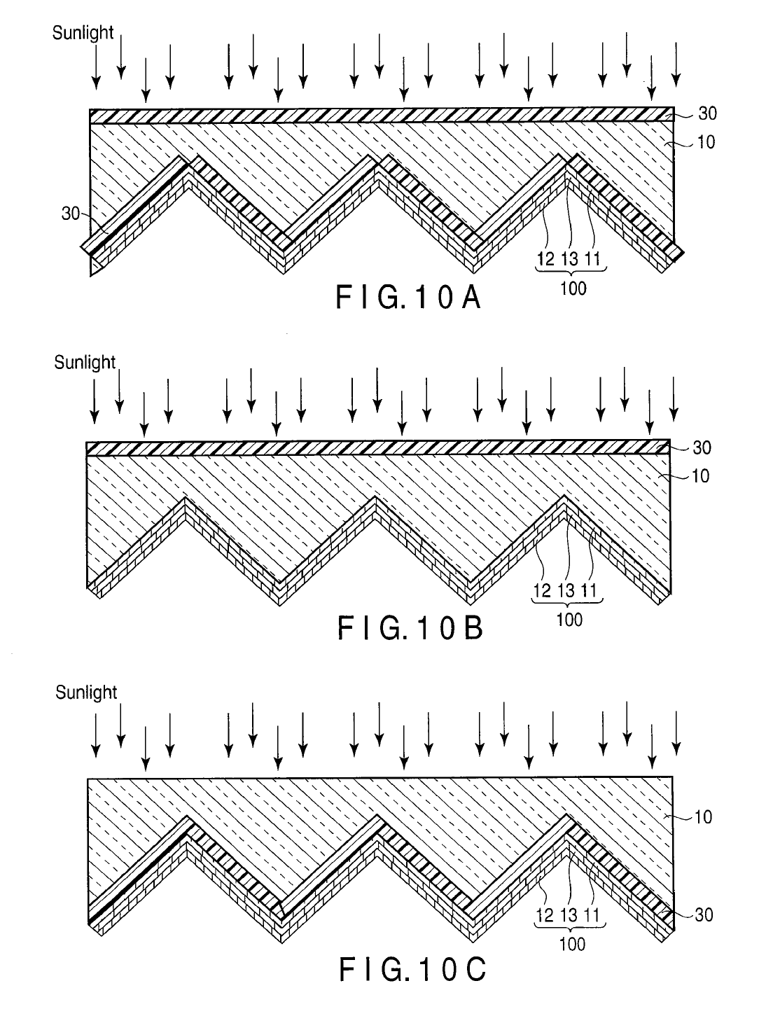

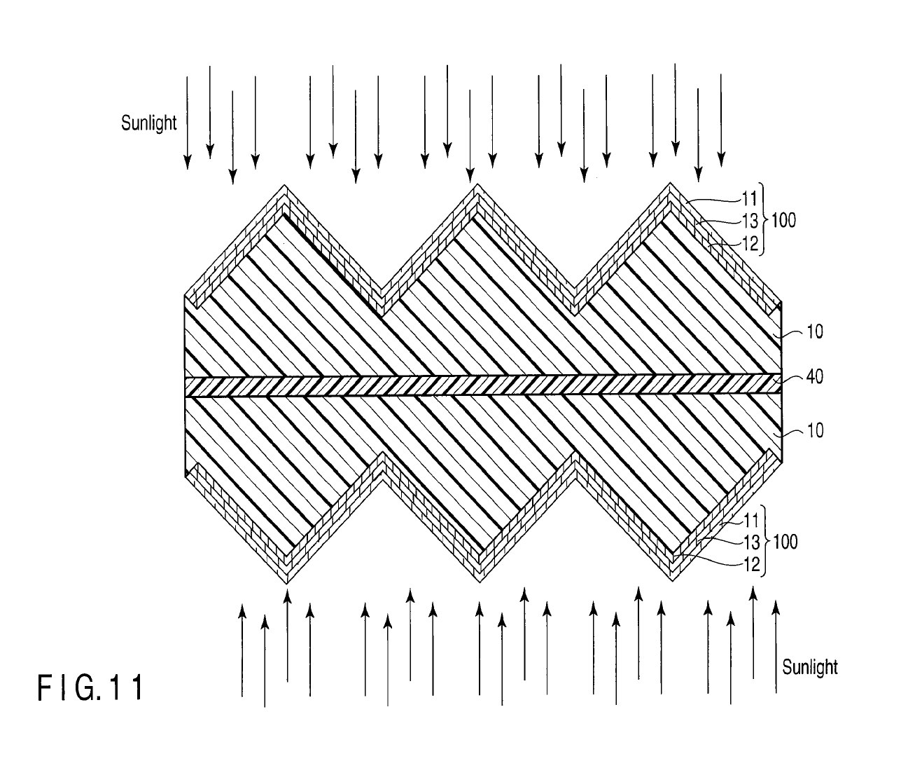

FIG. 10 is a cross-sectional view of the organic photovoltaic cell according to the sixth embodiment. An antireflection film 30 is provided in the organic photovoltaic cell of FIG. 10. Complete reflection of light on the substrate 10 of the solar cell causes the problem that light cannot be effectively trapped into the interior of the device. Reflection of light on the substrate 10 of the solar cell can be prevented by providing the antireflection film 30. When light enters from the side of the substrate 10, it is effective to provide the antireflection film 30 on both the light incidence plane of the substrate 10 and the interface of substrate 10 and solar cell 100 as shown in FIG. 10A. Alternatively, the antireflection film may be provided on either the light incidence plane or the interface as shown in FIG. 10B and FIG. 10C.

As the antireflection film 30, use can be made of a film resulting from application of a general-purpose antireflection coating, a sheet of antireflection film, etc. These can be applied in given thickness and shape. As the material capable of antireflection, there can be mentioned an inorganic material, such as titanium oxide, or an organic material, such as an acrylic resin or a polycarbonate resin.

It is preferred for the antireflection film for use in solar cells to be one having a moth-eye minute projecting structure. The film with a projecting structure, as the refractive index in the thickness direction continuously changes, can allow most of light incident upon the film to transmit substantially without any reflection. The moth-eye configuration can be produced by making a metal mold with finely rugged surface in accordance with a nanoimprint method and transferring the pattern of the metal mold to a resin sheet, an inorganic SOG, an organic SOG film or the like. Alternatively, using a titanium oxide self-organizing control technique or the like, a coating material or the like with the antireflection capability based on the same principle as that of the moth-eye structure may be prepared and applied.

In another embodiment, the power conversion efficiency may be enhanced by providing a layer capable of converting short-wave components of sunlight to long-wave components. For example, the power conversion efficiency can be enhanced by coating the surface of the substrate with a europium complex.

FIG. 11 is a cross-sectional view of the organic photovoltaic cell according to the seventh embodiment.

Referring to FIG. 11, use can be made of two solar cells each including a multislope cell bonded together. In particular, the bonded cells can be fabricated by a method, for example, in which a new substrate 40 is provided and solar cells each with a multislope cell are bonded to the obverse and reverse of the substrate. Further, devices can be formed on the obverse and reverse of a substrate by rendering the materials of both electrodes transparent.

Fabricating multislopes on the obverse and reverse of a substrate is effective when light enters from a plurality of directions. For example, such a solar cell may be used in the form of being erected on the ground (screen, barrier, etc.) or may be installed on a windowpane, a curtain or the like. If so, the probability of receiving light is increased with the result that the power generation efficiency can be enhanced.

An example of the method for manufacturing the above organic photovoltaic cells will be described below.

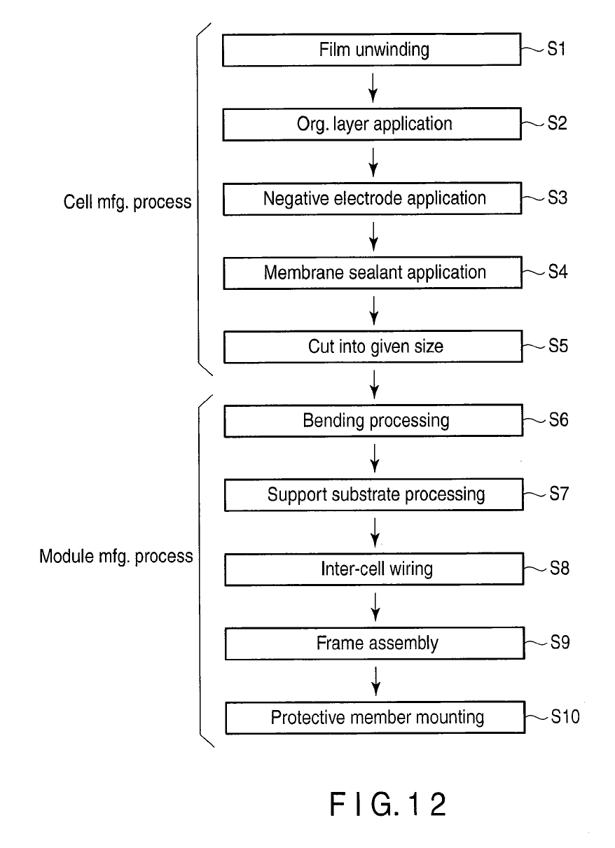

FIG. 12 is a flow chart showing an example of the method for manufacturing organic photovoltaic cells according to the embodiments. The manufacturing method can be largely divided into a cell manufacturing process (S1 to S5) for forming a device on a flexible film and a module manufacturing process (S6 to S10) for processing the manufactured cell into a concertina structure and assembling the same into a module. First, a film as a substrate for organic layers and electrodes is unwound (S1). The film may be one on which one of the electrodes has been formed in advance. Organic layers and electrodes are sequentially formed on the unwound film by coating (S2 and S3). A membrane sealant is applied on the electrodes (S4). The membrane sealant is capable of protecting the device from oxygen and moisture. In particular, using, for example, a thermosetting or UV-hardenable epoxy resin as a fixing agent, the surface protection is attained by a glass or metal plate, or a resin film (PET, PEN, PI, EVOH, CO, EVA, PC, PES or the like) provided on its surface with a film of inorganic material or metal (silica, titania, zirconia, silicon nitride, boron nitride, Al or the like). Further, the prolongation of device life can be expected by filling a sealing space with a drying agent or an oxygen absorber. Thereafter, the cell is cut into a size conforming to the object (S5).

Subsequently, the module manufacturing process is carried out. First, the cells obtained in the cell manufacturing process are processed (S6). This processing is performed according to necessity, for example, when the cells are arranged in a concertina structure as mentioned above in the fourth embodiment. For example, in the fourth embodiment, the processing includes bending the cells into a concertina structure and forming a fixing groove for fixing the cells on a support plate for fixing the cells (S6 and S7). After the processing, the cells are wired (S8). The members are fixed using a frame or the like (S9), and finally a protective member is mounted (S10).

The manufacturing method will be descried in greater detail below.

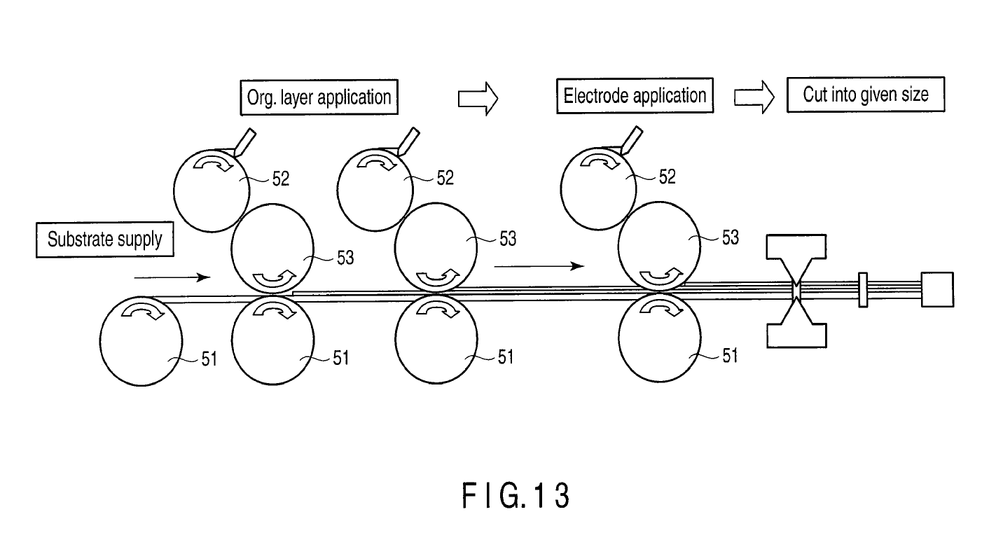

FIG. 13 is a view explaining the operation of coating conducted in the cell manufacturing process. The view explains the operation of applying the materials of an organic photovoltaic cell on a flexible film as a substrate according to a coating technique. In particular, explanation is made of the operation using a gravure.offset technique. However, the coating technique is not limited thereto, and in the process, use is made of other common coating techniques, such as a die coating technique, a meniscus coating technique or a gravure printing technique.

The film is in rolled form set on an unwinding machine. The film is continuously fed to a printing section by the rotation of the unwinding machine. The film passes through the gap between an impression cylinder 51 and a blanket cylinder 53. The film is cleaned by means of a UV cleaning unit for surface cleaning, not shown, before being fed to the printing section. In the printing section, a hole transport layer, a active layer and an electron transport layer are applied. Each of liquids for application is fed to a plate cylinder 52, transferred to a blanket cylinder 53 located on the underside of the plate cylinder 52 and applied onto the film. Thus, the materials are applied to the film. The applied materials must be dried, the drying not shown. Thereafter, an electrode layer is applied. Finally, the cell is cut into a size conforming to the object. The cut cells are processed in the module manufacturing process mentioned with reference to FIG. 12.

The organic photovoltaic cells according to the embodiments can be manufactured by the above easy method. Thus, the manufacturing cost is low, and high mass productivity can be realized. In the formation of the electrode layer, a vapor deposition or sputtering technique may be employed in place of the coating.

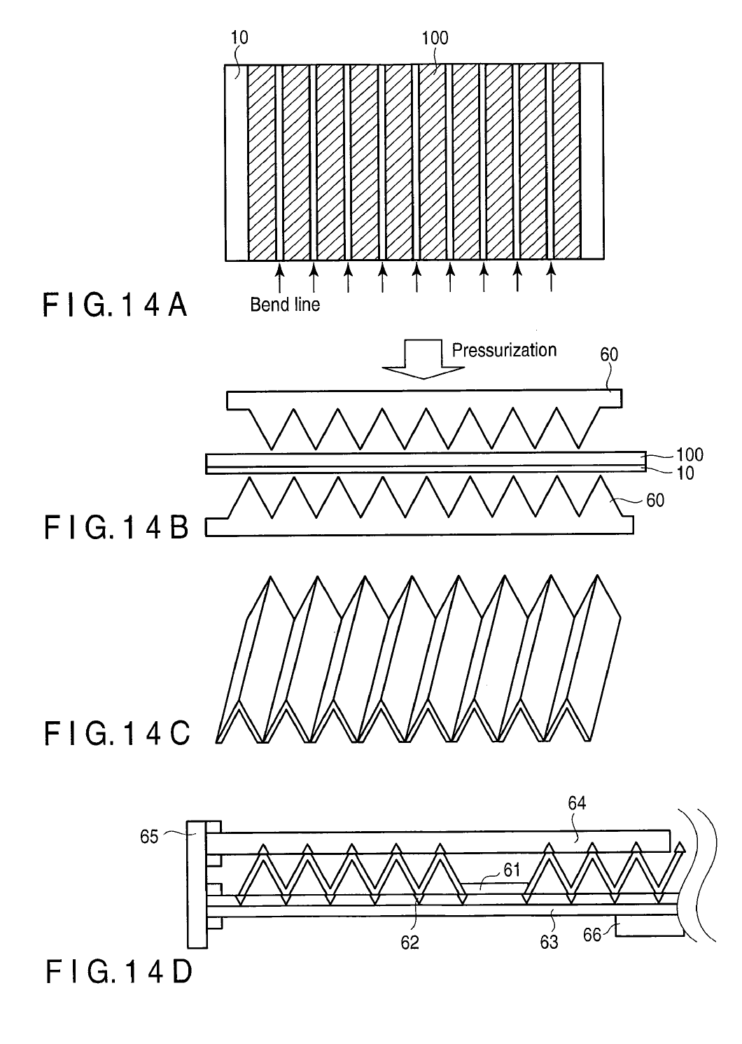

FIG. 14 is a view showing an example of module manufacturing process. In particular, the process in which the solar cells are arranged in the form of a concertina structure will be described below. First, a plurality of bend lines are affixed parallel to the longitudinal direction of the cell on the substrate 10 cut into a size complying to the object and cell 100 provided on the substrate (FIG. 14A). The solar cell 100 provided on the substrate 10 is divided into a plurality of cells (hereinafter also referred to as divided cells) as shown in FIG. 14A. Bend lines are affixed to the interstices between divided cells and divided cells. As when a cell is disposed in a bend line portion, cell short-circuiting occurs upon bending, it is needed to make a design ensuring that no cell is formed on bend line portions. Namely, device short-circuiting can be prevented by realizing a structure in which no cell is disposed at the ridge line portions of multislope cell top and groove portions. As a result, high yield can be attained, so that a highly reliable solar cell can be provided at low cost.

Thereafter, the bend-line-affixed substrate 10 and cell 100 are interposed between dies 60 provided on the surfaces thereof with concertina configurations, and pressure is applied from the both sides to thereby attain cell bending (FIG. 14B). At the pressurization, heat may be applied according to necessity. The operation of affixing bend lines is not essential. The flexible substrate can be deformed and bent while heating, and the substrate can be mechanically bent without bend lines. As another bending method, a flexible substrate may be disposed on the surface of the substrate molded into a multislope form in advance.

The thus obtained solar cell has the shape of FIG. 14C. Finally, the obtained solar cell 100 with a concertina structure is fixed and coupled with other members to thereby complete a module (FIG. 14D). In particular, a plurality of cells are connected to each other by means of an interconnector 61 and are fixed on a support plate 63 provided with a cell fixing groove 62. The whole is accommodated in a module unit including a transparent protective plate 64 and a frame 65, and wiring as in a terminal box 66 is carried out. As the material of the transparent protective plate 64, use can be made a glass substrate, a transparent resin such as polycarbonate, or the like.

Further processing may be carried out in order to remove stain from the surface of the solar cell module. Such processing can prevent the attachment of stain to the organic photovoltaic cell for a prolonged period of time and can prevent the drop of power conversion efficiency by stain. Such processing can be accomplished by, for example, the following methods.

Alternating current (AC) Cleaning Method: In multislope cells, as dust or other dirt is likely to accumulate on especially valley bottom portions, taking measures therefor is desired. In particular, with respect to the accumulation of microparticles, such as dust, it is effective to employ the detachment and carrying of microparticles by electric field. When linear electrode wires are disposed at intervals of about 1 to 10 mm on the surface of an insulating protective film provided on a cell surface and such a voltage that the direction of electric field is changed over time between electrode wires is applied, charged microparticles vibrate in accordance with the change of the electric field, so that the microparticles are detached from the cell surface. Furthermore, using a traveling wave spatially moving through the inter-electrode electric field makes it feasible to carry detached microparticles in a specified direction and remove the same from the cell surface. The electric field between adjacent electrodes is preferably in the range of 20 to 500 V/mm, more preferably around 100 to 200 V/mm. It is also practicable to apply an alternating voltage of about 90 to 180° phase lag between adjacent electrodes and cause the same to propagate between the electrodes as a traveling wave. Still further, when setting is made so that periodically the above electric field is applied between cell auxiliary wirings, cleaning can be performed without the need to install a new electrode.

Application of surface self-cleaning layer containing titanium oxide: When a titanium oxide layer capable of photooxidation is provided on the uppermost surface of the solar cell module, the decomposition of adhering organic matter is accelerated so that cleaning and removal of surface stain can be attained.

Other: Another effective countermeasure to dirt includes providing a valley bottom with a slit of about 0.5 to 2 mm width along the valley line so that relatively large dirt of mm size falls through the slit to outside the cell.

The described manufacturing method can be employed in not only the manufacturing of the above cells with a concertina structure composed of a plurality of triangular waves but also the manufacturing of cells with a structure including a plurality of slopes of arbitrary configuration (namely, multislope structure).

The multislope cell can be efficiently manufactured by forming a device on a flexible planar substrate and bending the obtained matter into a multislope form. For example, the multislope can be manufactured by affixing bend lines to a flexible substrate having a device formed thereon and carrying out a deformation under pressure, heat, etc.

The manufacturing of the multislope cell can be facilitated by shrinking both ends of a flexible substrate provided with a device in the lateral direction and effecting such an adjustment that a bent top is located in a recessed portion provided in advance.

A seeker or a light intensity detector can be installed as ancillary equipment. When the organic photovoltaic cell using the multislope cell according to the embodiment of the present invention is installed on, for example, the roof of a house, the maximum effect can be obtained by mounting a sun seeker capable of steering the cell toward the direction of the sun.

When the organic photovoltaic cell is used in mobile equipment and the like, the user can freely regulate the angle with reference to the light source. The power generation efficiency can be improved by installing a circuit for displaying the direction in which the light intensity of the light source is high. For example, a liquid crystal level meter capable of light intensity display or the like is effectively used.

Now, the principle of the power generation of the organic photovoltaic cell will be described.

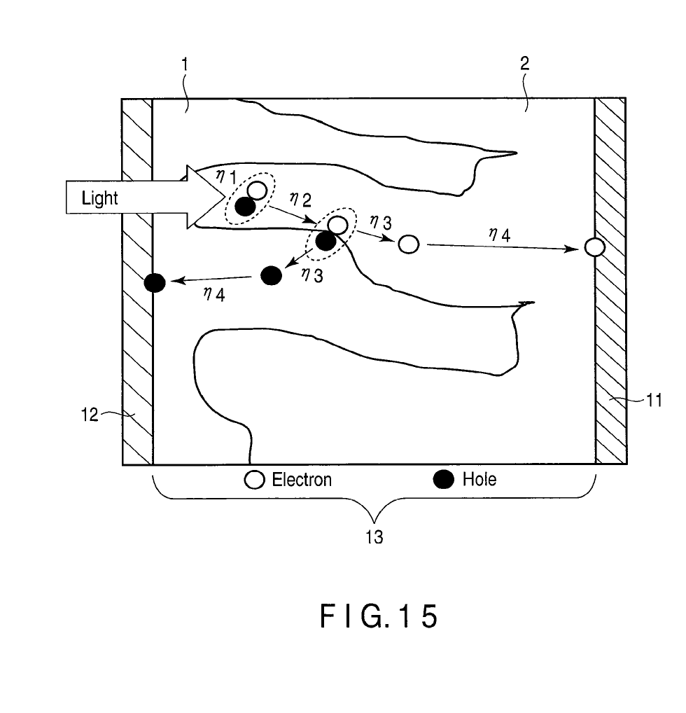

FIG. 15 is a view explaining the mechanism of the behavior of the bulk heterojunction solar cell. The photoelectric conversion process of the organic photovoltaic cell is largely divided into the step of light absorption by an organic molecule to thereby generate an exciter (a), the step of exciter transfer and diffusion (b), the step of charge separation of the exciter (c) and the step of charge transport to both poles (d).

In the step (a), a p-type organic semiconductor or an n-type organic semiconductor absorbs light to thereby generate an exciter. The generation efficiency thereof is denoted as η1. Subsequently, in the step (b), the generated exciter is transferred by diffusion to a p/n junction face. The diffusion efficiency thereof is denoted as η2. The exciter has its life, so that the transfer is only about the diffusion length. In the step (c), the exciter having reached the p/n junction face is separated into an electron and a hole. The efficiency of exciter separation is denoted as η3. Finally, in the step (d), individual optical carriers are transported through the p/n material to the electrodes and taken out into an external circuit. The transport efficiency is denoted as η4.

The efficiency of externally taking out generated carriers can be expressed by the following formula. The value thereof corresponds to the quantum efficiency of the solar cell.

η_{EQE}=η1·η2·η3·η4.

For enhancing the power conversion efficiency, the organic photovoltaic cell device is to be manufactured taking the characteristics of the steps (a) to (d) above into account. Namely, in the step (a), the active layer 100% absorbs incoming photons. In the steps (b) and (c), the transferability of organic semiconductor materials is to be high, thereby ensuring the p/n junction. In the step (d), carrier paths are to be formed to both poles, thereby realizing a short distance to electrodes, and there are no defects leading to traps.

A highly efficient device can be realized by manufacturing the organic photovoltaic cell on the basis of these premises. However, the current materials and film forming methods are far removed from the ideal. The organic photovoltaic cell has the problems of low exciton dissociation probability, short exciton diffusion length and low carrier transferability as compared with those of conventional inorganic solar cells. The reason therefor is that for the organic semiconductor, there are a multiplicity of parameters whose control is difficult, such as purity, molecular weight distribution and orientation.

A measure of thickening the active layer to thereby increase the ratio of absorption of photons can be contemplated for improvement in the step (a). Thickening the active layer increases the length of light path, thereby increasing the ratio of absorption of photons. However, the electrical resistance is increased in accordance with the increase of the thickness of the active layer, so that the trapping of carriers is likely to occur. Consequently, generated carriers fail to reach the electrodes, thereby lowering the power conversion efficiency.

Further, a measure of thinning the active layer to thereby reduce the inter-electrode distance can be contemplated for improvement in the step (d). Reducing the inter-electrode distance facilitates the reaching of generated carriers to the electrodes and also lowers the electrical resistance of the film. Thus, an increase of the power conversion efficiency may be presumed. However, when the active layer is thin, the amount of exciton generated in the step (a) is decreased. This is because the light absorption of the material used in the active layer is not so high that when the active layer is thin, photons escape outside without all being absorbed in the active layer. Therefore, the number of carriers is decreased, and the current is decreased. As a result, the power conversion efficiency is lowered.

As apparent from the above, thickening the active layer lowers the transport capacity for transporting carriers to the electrodes although the number of excitons generated is increased. On the other hand, thinning the active layer decreases the number of excitons generated although the transport of carriers to the electrodes is excellent. Therefore, both thickening and thinning the active layer end up in lowering of the power conversion efficiency.

In contrast, in the above embodiments, the light path length of the active layer can be increased while the thickness of the active layer is held within an optimum range by inclining the solar cell. Therefore, without causing the above problems, there can be provided a solar cell with enhanced power conversion efficiency.

The constituent members of the organic photovoltaic cells according to the embodiments will be described below.

(Substrate)

The substrate is for supporting other constituent members. It is preferred for the substrate 10 to be one capable of forming an electrode and not affected by heat or organic solvents. As the material of the substrate 10, there can be mentioned, for example, an inorganic material, such as non-alkali glass or quartz glass; a polymer film or plastic, such as polyethylene, polyethylene terephthalate (PET), polyethylene naphthalate (PEN), a polyimide, a polyamide, a polyamidoimide, a liquid crystal polymer or a cycloolefin polymer; a metal, such as stainless steel (SUS) or silicon; or the like. When the substrate 10 is disposed on the light incident side, a transparent substrate is used. When the electrode opposite to the substrate is transparent or translucent, an opaque substrate may be used. The thickness of the substrate is not particularly limited as long as it ensures a strength satisfactory for supporting other constituent members.

(Positive Electrode)

The positive electrode 11 is formed on the substrate 10. The material of the positive electrode 11 is not particularly limited as long as it is electrically conductive. Generally, a transparent or translucent conductive material is formed into a film by using a vacuum vapor deposition technique, a sputtering technique, an ion plating technique, a plating technique, a coating technique or the like. As the transparent or translucent electrode material, there can be mentioned a conductive metal oxide film, a translucent metal thin-film or the like. In particular, use is made of a film (NESA, etc.) of conductive glass containing indium oxide, zinc oxide, tin oxide, indium.tin.oxide (ITO) being a complex thereof, fluorine-doped tin oxide (FTO), indium.zinc.oxide or the like, gold, platinum, silver, copper, etc. ITO and FTO are especially preferred. Also, as the electrode material, use may be made of an organic conductive polymer, such as polyaniline or its derivative, polythiophene or its derivative, etc. The thickness of the positive electrode 11 when the material is ITO is preferably in the range of 30 to 300 nm. When the thickness is less than 30 nm, the conductivity is decreased, and the resistance becomes high, thereby causing lowering of the power conversion efficiency. When the thickness exceeds 300 nm, the ITO loses its flexibility, so that when a stress is applied, the ITO cracks. It is preferred for the sheet resistance of the positive electrode 11 to be as low as possible, for example, 10Ω/□ or less. The positive electrode 11 may be a monolayer or a multilayer containing materials exhibiting different work functions.

(Hole Transport Layer)

The hole transport layer 14 is optionally interposed between the positive electrode 11 and the active layer 13. The functions of the hole transport layer 14 are, for example, to level any unevenness of the underneath electrode to thereby prevent short-circuiting of the solar cell device, to efficiently transport holes only and to prevent the annihilation of exciters generated in the vicinity of the interface with the active layer 13. As the material of the hole transport layer 14, use can be made of a polythiophene polymer such as PEDOT/PSS (poly(3,4-ethylenedioxythiophene)-poly(styrene sulfonate)), or an organic semiconductor polymer such as polyaniline or polypyrrole. As representative polythiophene polymer products, there can be mentioned, for example, Clevios PH500(trade name), Clevios PH(trade name), Clevios PVPA1 4083(trade name) and Clevios HIL1.1(trade name) all available from Stark GmbH.

When Clevios PH500(trade name) is used as the material of the hole transport layer 14, it is preferred for the thickness thereof to be in the range of 20 to 100 nm. When the layer is extremely thin, it is no longer capable of preventing the short-circuiting of the underneath electrode, so that short-circuiting occurs. On the other hand, when the layer is extremely thick, the film resistance becomes high to thereby restrict generated currents. Thus, the power conversion efficiency is lowered.

The method of forming the hole transport layer 14 is not particularly limited as long as the method is suitable for the formation of a thin film. For example, the layer can be applied by a spin coating technique or the like. The material of the hole transport layer 14 is applied in a desired thickness and dried by heating by means of a hot plate or the like. The heat drying is preferably carried out at 140 to 200° C. for several minutes to about 10 minutes. Preferably, the applied solution is filtered before use.

(Active Layer)

The active layer 13 is disposed between the positive electrode 11 and the negative electrode 12. The solar cell of the embodiment is one of bulk heterojunction type. The bulk heterojunction solar cell is characterized in that a p-type semiconductor and an n-type semiconductor are mixed together in the active layer to thereby have a microlayer separation structure. In the bulk heterojunction solar cell, a p-type semiconductor and an n-type semiconductor mixed together produces a nano-order sized pn junction in the active layer, and electric current is obtained by utilizing a photocharge separation occurring on a junction interface. The p-type semiconductor is composed of a material with electron donating properties. On the other hand, the n-type semiconductor is composed of a material with electron accepting properties. In the embodiments, at least either the p-type semiconductor or the n-type semiconductor may be an organic semiconductor.

As the p-type organic semiconductor, use can be made of, for example, polythiophene or its derivative, polypyrrole or its derivative, a pyrazoline derivative, an arylamine derivative, a stilbene derivative, a triphenyldiamine derivative, oligothiophene or its derivative, polyvinylcarbazole or its derivative, polysilane or its derivative, a polysiloxane derivative containing an aromatic amine on its side chain or principal chain, polyaniline or its derivative, a phthalocyanine derivative, porphyrin or its derivative, polyphenylenevinylene or its derivative, polythienylenevinylene or its derivative, etc. These may be used in combination. Also, use can be made of copolymers thereof. For example, there can be mentioned a thiophene-fluorene copolymer, a phenyleneethynylene-phenylenevinylene copolymer, or the like.

Preferred p-type organic semiconductors are polythiophene being a conductive polymer with π-conjugation and its derivatives. Polythiophene and its derivatives can ensure high stereoregularity and exhibit relatively high solubility in solvents. Polythiophene and its derivatives are not particularly limited as long as they are compounds having a thiophene skeleton. As specific examples of the polythiophene and derivatives thereof, there can be mentioned a polyalkylthiophene, such as poly-3-methylthiophene, poly-3-butylthiophene, poly-3-hexylthiophene, poly-3-octylthiophene, poly-3-decylthiophene or poly-3-dodecylthiophene; a polyarylthiophene, such as poly-3-phenylthiophene or poly-3-(p-alkylphenylthiophene); a polyalkylisothionaphthene, such as poly-3-butylisothionaphthene, poly-3-hexylisothionaphthene, poly-3-octylisothionaphthene or poly-3-decylisothionaphthene; polyethylenedioxythiophene; and the like.

In recent years, derivatives such as PCDTBT (poly[N-9″-hepatadecanyl-2,7-carbazole-alt-5,5,-(4′,7′-di-2-thienyl-2′,1′,3′-benzothiazole)]) being a copolymer of carbazole, benzothiazole and thiophene are known as compounds realizing an excellent power conversion efficiency. The structure of PCDTBT is shown below.

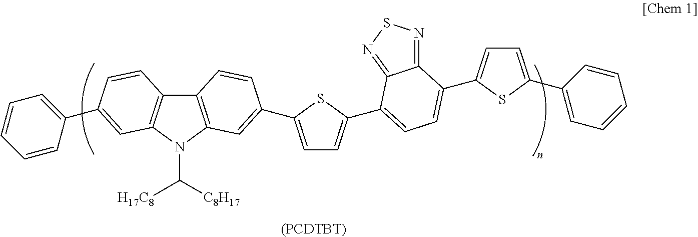

Any of these conductive polymers can be formed into a film by dissolving the same in a solvent and applying the solution by a coating technique. Therefore, these conductive polymers are advantageous in that an organic photovoltaic cell of large area can be manufactured at low cost by a printing technique or the like using inexpensive equipment.

Fullerene and its derivatives are appropriately used as the n-type organic semiconductor. The employed fullerene derivatives are not particularly limited as long as the derivatives contain fullerene skeletons. For example, there can be mentioned derivatives including C60, C70, C76, C78, C84, etc. as fundamental skeletons. In the fullerene derivatives, the carbon atoms of each fullerene skeleton may be modified by arbitrary functional groups, and such functional groups may be bonded to each other to thereby form a ring. The fullerene derivatives include fullerene-bonded polymers. Fullerene derivatives having a functional group of high affinity to solvents, thereby exhibiting a high solubility in solvents, are preferred.

As the functional groups that can be introduced in the fullerene derivatives, there can be mentioned, for example, a hydrogen atom; a hydroxyl group; a halogen atom, such as a fluorine atom or a chlorine atom; an alkyl group, such as a methyl group or an ethyl group; an alkenyl group, such as a vinyl group; a cyano group; an alkoxy group, such as a methoxy group or an ethoxy group; an aromatic hydrocarbon group, such as a phenyl group or a naphthyl group; an aromatic heterocyclic group, such as a thienyl group or a pyridyl group; and the like. For example, there can be mentioned a hydrogenated fullerene, such as C60H36 or C70H36; an oxide fullerene, such as C60 or C70; a fullerene metal complex; and the like.

It is most preferred to use 60PCBM ([6,6]-phenylC61 butyric methyl ester) and 70PCBM ([6,6]-phenylC71 butyric methyl ester) as fullerene derivatives among the above-mentioned compounds.

Specific examples of the structures of the fullerene derivatives for use in the embodiments will be shown below.

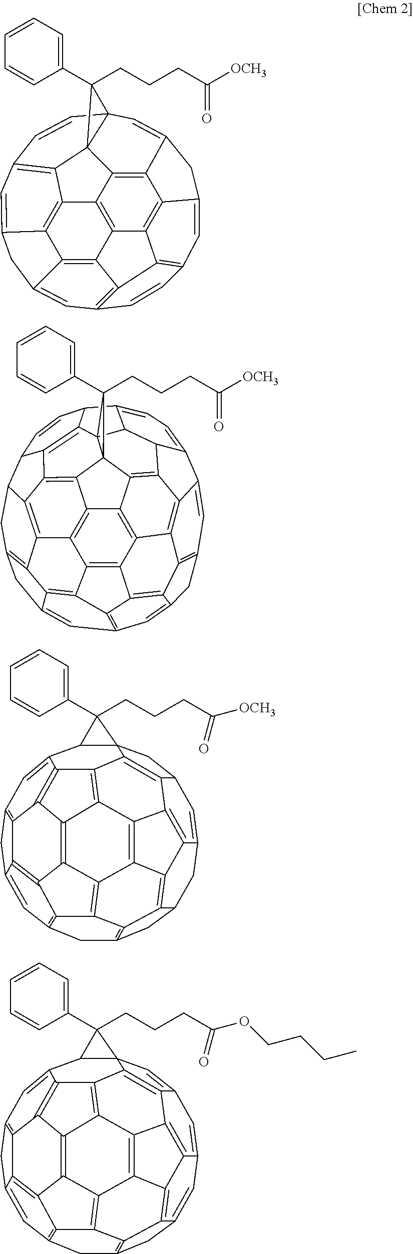

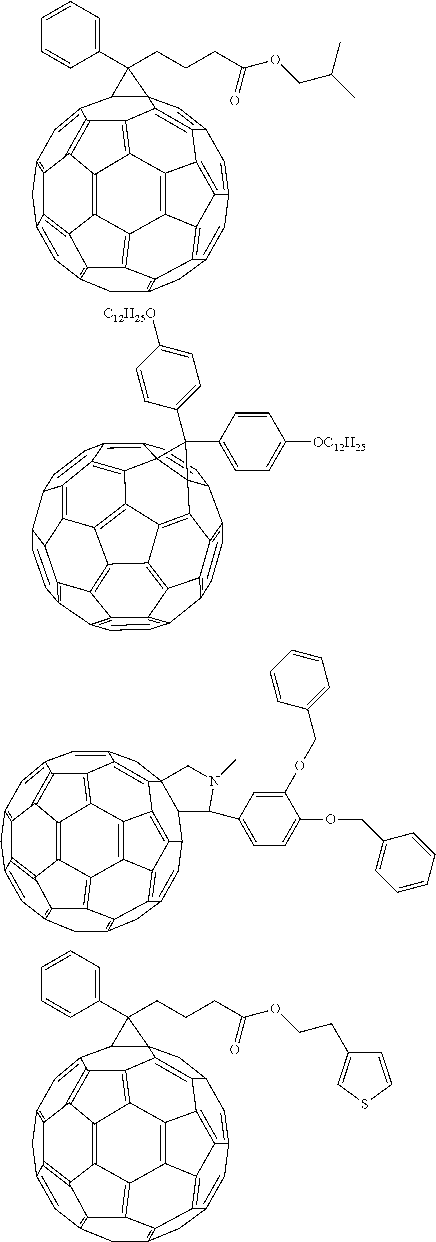

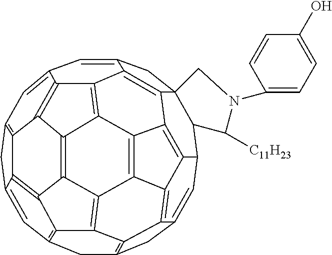

When an unmodified fullerene is used, using C70 is preferred. The fullerene C70 exhibits a high optical carrier generating efficiency, thereby being suitable for use in an organic photovoltaic cell.

With respect to the mixing ratio of n-type organic semiconductor and p-type organic semiconductor in the active layer, when the p-type semiconductor is any of P3AT series, approximately n:p=1:1 is preferred. When the p-type semiconductor is any of PCDTBT series, approximately n:p=4:1 is preferred.

In the application of an organic semiconductor by coating, the semiconductor must be dissolved in a solvent. As suitable solvents, there can be mentioned, for example, an unsaturated hydrocarbon solvent, such as toluene, xylene, tetralin, decalin, mesitylene, n-butylbenzene, sec-butylbenzene or tert-butylbenzene; a halogenated aromatic hydrocarbon solvent, such as chlorobenzene, dichlorobenzene or trichlorobenzene; a halogenated saturated hydrocarbon solvent, such as carbon tetrachloride, chloroform, dichloromethane, dichloroethane, chlorobutane, bromobutane, chloropentane, chlorohexane, bromohexane or chlorocyclohexane; and an ether, such as tetrahydrofuran or tetrahydropyran. Of these, halogenated aromatic solvents are preferred. These solvents may be used alone or in combination.

As the technique for forming the solution into a film by coating, there can be mentioned a spin coat technique, a dip coat technique, a casting technique, a bar coat technique, a roll coat technique, a wire bar coat technique, a spray technique, a screen printing technique, a gravure printing technique, a flexographic printing technique, an offset printing technique, a gravure offset printing technique, a dispenser coat technique, a nozzle coat technique, a capillary coat technique, an inkjet technique or the like. These coating techniques can be used alone or in combination.

When the cell is disposed in a V-shaped arrangement, in the coating using a spin coater, uniform coating can be realized by disposing the cell with a displacement from the center and providing a V-groove in the direction of centrifugal force. When a dipping technique is used, backside stain can be prevented by superimposing two cells arranged into V-shaped form one upon the other and carrying out simultaneous coating.

(Electron Transport Layer)

The electron transport layer 15 is optionally disposed between the negative electrode 12 and the active layer 13. The functions of the electron transport layer 15 are to efficiently transport electrons only while blocking holes and to prevent the annihilation of excitons generated at the interface of the active layer 13 and the electron transport layer 15.

As the material of the electron transport layer 15, there can be mentioned a metal oxide, for example, amorphous titanium oxide obtained by hydrolyzing a titanium alkoxide by a sol gel method, or the like. The film forming method is not particularly limited as long as the method is suitable for the formation of a thin film. For example, there can be mentioned a spin coat technique. When titanium oxide is used as the material of the electron transport layer, the thickness of the thus formed layer is preferably in the range of 5 to 20 nm. When the thickness is smaller than the above range, a hole block effect lessens, so that generated excitons deactivate before dissociation into an electron and a hole. Thus, efficiently taking out current is infeasible. On the other hand, when the thickness is extremely large, the film resistance becomes large to thereby restrict generated currents. Thus, the power conversion efficiency is lowered. The coating solution is preferably filtered before use. After coating in a given thickness, the layer is dried by heating by means of, for example, a hot plate. Heat drying is preferably carried out at 50 to 100° C. for several minutes to about 10 minutes in air while promoting hydrolysis.

(Negative Electrode)

The negative electrode 12 is superimposed on the active layer 13 (or electron transport layer 15). A conductive material is formed into a film by a vacuum vapor deposition technique, a sputtering technique, an ion plating technique, a plating technique, a coating technique or the like. As the electrode material, there can be mentioned a conductive metal thin-film, a metal oxide film or the like. When the positive electrode 11 is formed of a material of high work function, it is preferred to use a material of low work function in the negative electrode 12. Examples of materials of low work function include an alkali metal, an alkaline earth metal and the like. Specifically, there can be mentioned Li, In, Al, Ca, Mg, Sm, Tb, Yb, Zr, Na, K, Rb, Cs, Ba and alloys of these.

The negative electrode 12 may be a monolayer or a multilayer containing materials of different work functions. The material may be an alloy including at least one of the above materials of low work function and a member selected from among gold, silver, platinum, copper, manganese, titanium, cobalt, nickel, tungsten, tin and the like. Examples of the alloys include a lithium-aluminum alloy, a lithium-magnesium alloy, a lithium-indium alloy, a magnesium-silver alloy, a magnesium-indium alloy, a magnesium-aluminum alloy, an indium-silver alloy, a calcium-aluminum alloy and the like.

The film thickness of the negative electrode 12 is in the range of 1 to 500 nm, preferably 10 to 300 nm. When the film thickness is smaller than the above range, the resistance becomes so large that generated charges cannot satisfactorily be transferred to an external circuit. When the film thickness is very large, the formation of the film of the negative electrode 12 takes a prolonged period of time, so that the temperature of the material is increased to thereby damage the organic layers and cause performance deterioration. Further, the amount of material used is large, so that the period of occupying the film forming apparatus is prolonged to thereby cause a cost increase.

### EXAMPLES

### Example 1

Organic photovoltaic cells in which solar cells are respectively inclined by 80°, 70°, 60° and 45° against the horizontal plane were prepared and compared with each other. An organic photovoltaic cell in which solar cells are not inclined was prepared in the same manner as a comparative example.

First, organic semiconductor solid contents contained in a active layer were prepared.

Ten (10) parts by weight of PCDTBT (poly[N-9″-hepatadecanyl-2,7-carbazole-alt-5,5-(4′,7′-di-2-thienyl-2′,1′,3′-benzothiazole)]) produced by 1-Material as a p-type organic semiconductor and 40 parts by weight of 70PCBM ([6,6]-phenylC71 butyric methyl ester) produced by SOLENNE as an n-type organic semiconductor were mixed together.

Subsequently, 1 ml of orthodichlorobenzene as a solvent and 30 mg of above solid contents were placed in a sample bottle, and irradiated with ultrasonic waves at 50° C. for two hours in an ultrasonic washer (model US-2, manufactured by Iuchi Seieido Co., Ltd.), thereby dissolving the solid contents in the solvent. Thus, a coating solution for forming a active layer was obtained. Finally, the coating solution was passed through a 0.2 μm filter.

As a substrate, use was made of a 20 mm×20 mm 0.7 mm-thick glass substrate. The glass substrate was laminated with a 140 nm-thick ITO transparent conductive layer by a sputtering technique, thereby obtaining a glass substrate with ITO. Photolithography was conducted on the ITO portion to thereby form a 3.2 mm×20 mm rectangular pattern.

The resultant substrate was ultrasonically washed with pure water containing 1% of surfactant (NCW1001 produced by Wako Pure Chemical Industries, Ltd.) for 5 minutes and further washed with running pure water for 15 minutes. Still further, the substrate was ultrasonically washed with acetone for 5 minutes and ultrasonically washed with isopropyl alcohol (IPA) for 5 minutes. The finally washed substrate was dried in a 120° C. thermostat for 60 minutes.

Thereafter, UV treatment of the substrate was performed for 10 minutes to thereby render the surface of the substrate hydrophilic.

The film formation by coating was carried out through the following operations.

First, in air, an aqueous solution of PEDOT/PSS (poly(3,4-ethylenedioxythiophene)-poly(styrene sulfonate) [trade name Clevios PH500] produced by Stark GmbH) for forming a hole transport layer was formed by a spin coat technique into a 54 nm-thick layer on the glass substrate with ITO, and dried on a hot plate at 200° C. for 5 minutes. The aqueous solution of PEDOT/PSS was passed through a 0.1 μm filter before use.

Secondly, in a nitrogen-flushed glove box, the above-mentioned coating solution for forming a active layer was dropped onto the hole transport layer, and a 90 nm-thick organic semiconductor layer was formed utilizing a spin coat technique. Thereafter, in the same atmosphere, the laminated substrate was dried by heating on a hot plate at 70° C. for 60 minutes. The coating solution was passed through a 0.2 μm filter before use.

Thirdly, an amorphous titanium oxide layer as an electron transport layer was prepared by forming a solution produced by a sol gel method into a film. The titanium oxide solution was produced through the following operation. Namely, 5 ml of titanium isopropoxide, 25 ml of 2-methoxyethanol and 2.5 ml of ethanolamine were placed in a nitrogen-flushed 50 ml three-necked flask (equipped with stirring means, a reflux device and temperature adjusting means) and refluxed at 80° C. for two hours and at 120° C. for an hour. The thus obtained titanium oxide precursor solution was diluted 150-fold with IPA. The resultant solution was passed through a 0.2 μm filter.

This solution was dropped onto the active layer, and an electron transport layer was formed so as to have a thickness of 15 nm by a spin coat technique. The laminated substrate was dried by heating on a hot plate at 80° C. for 10 minutes. The coating and drying operations for the electron transport layer were carried out in air as a reaction of producing titanium oxide by hydrolysis was involved. The reason therefor is that air contains moisture, so that in air, the moisture can be utilized to advance the reaction.

Fourthly, a negative electrode was prepared by a vapor deposition technique using a vacuum vapor deposition apparatus. The glass substrate with ITO having been coated with the active layer was set on a substrate holder, overlaid with a negative electrode pattern mask, and placed in a vapor deposition machine. The negative electrode pattern mask had a rectangular slit of 3.2 mm width, and was disposed so that the ITO layer and the slit intersected with each other. Thus, the area of the organic photovoltaic cell device was the area of the intersecting portion, being 0.1024 cm² (3.2 mm×3.2 mm). Evacuation was performed until a vacuum degree of 3×10⁻⁶ Torr, and resistance heating of an Al wire rod was conducted. An 80 nm-thick aluminum layer was formed by vapor deposition.

Fifthly, the substrate on which vapor deposition was completed was annealed on a hot plate at 150° C. for 30 minutes.

A sealing glass having its center cut off was bonded to the substrate after the annealing with the use of an epoxy resin, thereby sealing the substrate after the annealing.

Finally, extraction electrodes were drawn out from the positive and negative electrodes, thereby completing an organic photovoltaic cell.

(Comparison of the Current-Voltage Characteristics)

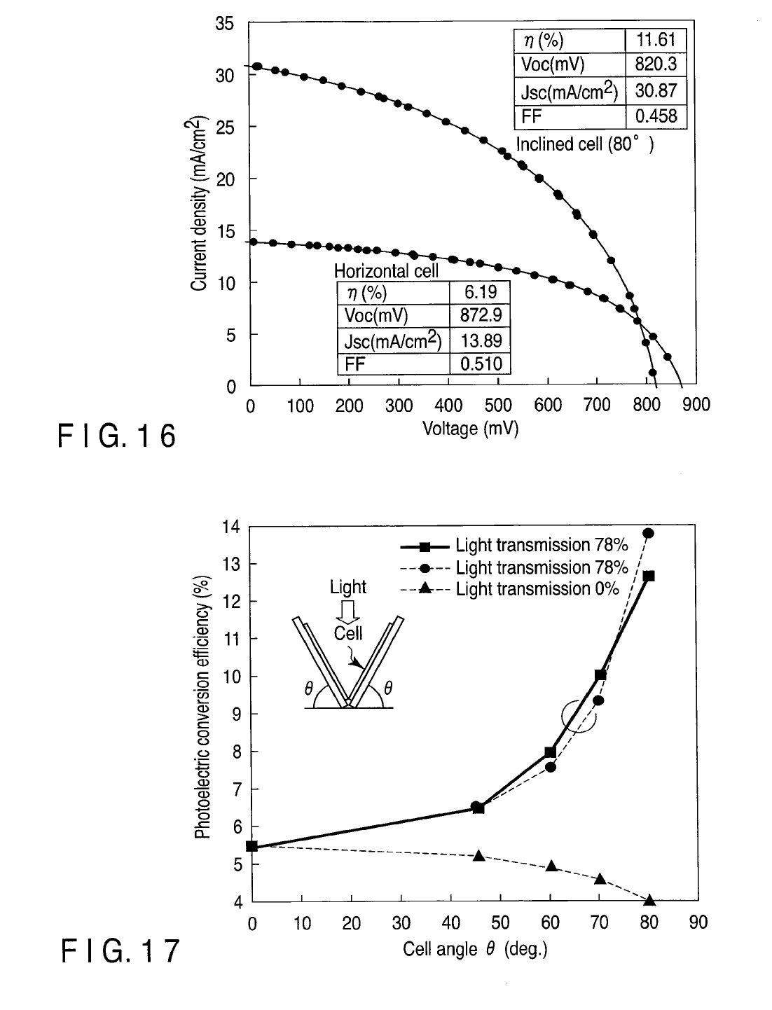

The current-voltage characteristics were compared between the solar cell inclined by 80° against the horizontal plane (inclined cell) and the solar cell not inclined (horizontal cell). The results are shown in FIG. 16. In the measurement, in order to realize a practical cell configuration, use was made of a pair of cells inclined by an angle of θ which were arranged in a V-shape as shown in FIG. 2. Accordingly, the light reflected from the opposed cell contributed to measurement results.

With respect to the horizontal cell, the efficiency was 6.19%. With respect to the 80° inclined cell, the efficiency was improved to 11.61%. Thus, the effect of the embodiments of the present invention was ascertained. The conversion efficiency of the inclined cell was about 1.9 times that of the horizontal cell. The current density J_{SC} of the inclined cell was about 2.2 times that of the horizontal cell, being 30.87 mA/cm².

Subsequently, the photoelectric conversion efficiencies were compared with each other while changing the inclination angle. In the measurement, as mentioned above, use was made of a pair of cells arranged in a V-shape. The measurement was performed using an electric output measuring equipment (manufactured by Maki Manufacturing Co., Ltd.). As the light source for measurement, use was made of a standard light source capable of simulating pseudo sunlight while obtaining an output of 100 mW/cm² irradiation illuminance by means of a solar simulator capable of reproducing AM1.5. The 1V characteristics by electron load were measured using this equipment, thereby determining the power conversion efficiency. In the calculation of the conversion efficiency, use was made of an experimental fact that in the organic photovoltaic cell, the relationship between the intensity of incident light and the conversion efficiency is linear over a wide range of light intensity.

The relationship between cell angle θ and power conversion efficiency is shown in FIG. 17. The solid line indicates the results of actually performed experiments, and the dashed line indicates the results obtained by simulation. The simulation was performed according to a model taking the absorption and reflection of incident light into consideration.

When θ was 45°, the ratio of increase of the power conversion efficiency was small. However, the ratio sharply increased from 60°, and a high conversion efficiency was exhibited at 70° and 80°.

Simulation for investigating the optimal value of the light transmission of the active layer was carried out. Specifically, the quantity of light absorbed by the active layer was determined on the basis of, for example, experimental data on the absorbancy index, refractive index and light transmission of each of the layers of the cell prepared in Example 1. The quantity of light was reduced to the conversion efficiency. It is apparent from the graph that when the light transmission of the active layer was 78%, the simulation calculation results relatively satisfactorily reproduced the actual measurement results. In contrast, it was seen that when the active layer had absorbed all light, namely when the light transmission of the active layer was 0%, the conversion efficiency lowered in accordance with the increase of the inclination of the cell.

(Simulation of Intra-Cell Efficiency Distribution)

In the V-shaped structure composed of opposed cells, light incoming from above is reflected on a cell surface and collected in the valley bottom portion of the V shape. Accordingly, it is intuitively expected that the light intensity becomes stronger in accordance with approaching to the valley bottom portion of the V shape with the result that apparent conversion efficiency is increased. For clarifying this, the light path in the V shape was calculated, and an intra-cell efficiency distribution was simulated. As the object of the simulation, use was made of solar cells prepared in Example 1 which were inclined by 80° against the horizontal plane and opposed to each other into a V-shaped arrangement.

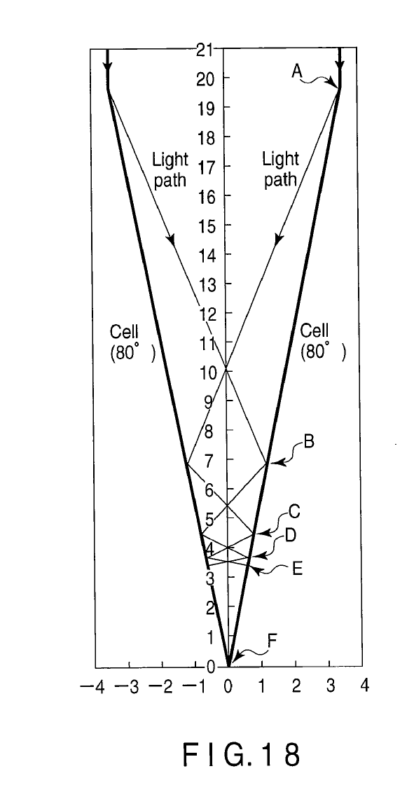

FIG. 18 is a view showing the light path inside the V-shaped cell. Attention is drawn to the right cell of FIG. 18. The light path upon the incidence of light on point A of the uppermost portion of the cell from perpendicular above is predicted. When the inclination angle θ of the cell is 80°, the light having struck the point A at an angle of 10° against the cell is reflected to become a first-order reflected light. The first-order reflected light strikes the location of the left cell opposed to point B at an angle of 30° against the cell, is reflected there, and strikes point C of the right cell as a second-order reflected light. Similarly, the light having struck the uppermost portion of the left cell is reflected there and strikes the point B of the right cell at an angle of 30° against the cell as a first-order reflected light. From this analysis, it is seen that the region A to B of the right cell is irradiated with incident light only while the region B to C is irradiated with incident light and a first-order reflected light. Calculation was made taking into account that at every repetition of reflection and incidence, the angle of incident light against the cell is changed and the light flux is squeezed, and that the degree of light collection becomes high in accordance with approaching to the valley bottom.

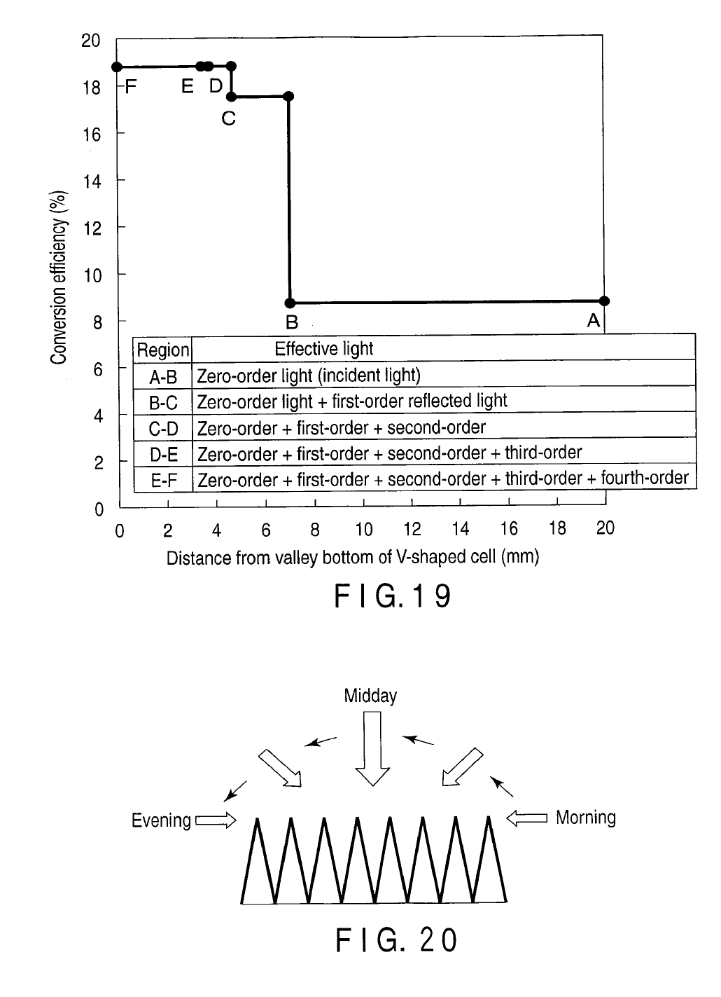

The calculation results for the power conversion efficiency distribution inside the V-shaped cell are shown in FIG. 19. The characters A to F of FIG. 19 corresponds to those of FIG. 18. The 8.7% obtained as a measured value was used as the conversion efficiency in the region A-B. Calculation results are shown in the region B-C and subsequent regions. In the region B-C, the effect of the first-order reflected light was conspicuous, and the efficiency approximately doubled. In the region E-F in which up to a fourth-order reflection was considered, the conversion efficiency reached 19.0%. From these results, it was seen that in the V-shaped cell, as expected, an efficiency distribution existed in individual regions of the cell, and that in the measurement of efficiency, attention should be drawn to the point of measurement. In the measurement of efficiency in FIG. 17 and FIG. 19, measurement was performed using the cell covering the entirety of the valley bottom and peak of the V shape, so that it was thought that correct values were obtained.

(Simulation of Light Directional Characteristics of Solar Cell)

Now, the light directional characteristics of the solar cell were studied by simulation. Namely, with respect to the multislope cell, the change of electrical energy output upon light incidence whose angle ranged over 180° from morning sun to evening sun was simulated. FIG. 20 is a view showing changes of sunlight incidence angle of a day with respect to the multislope cell. As the method for predicting all the reflections and light collections in the V-shaped cell has been established, the daily electrical energy output can be calculated by providing the intensity and angle of incident light as initial conditions. When the angle of incident light is shallow (namely, morning sun or evening sun), however, shadowing must be taken into consideration.

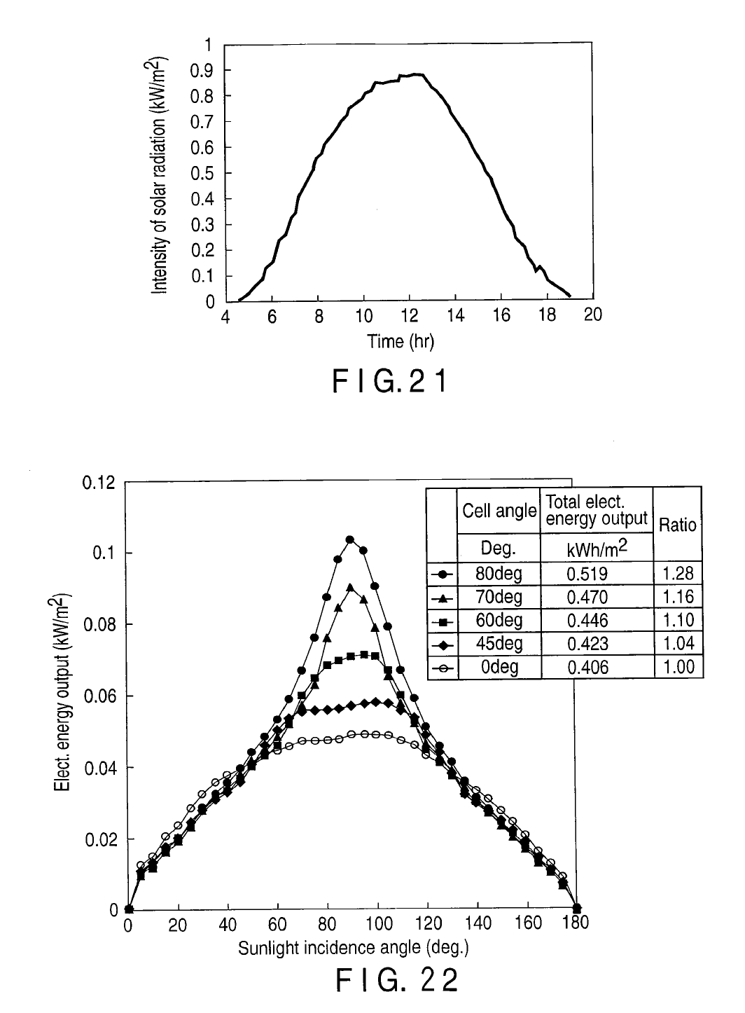

It is known for the results of solar radiation intensity measurements of a day in summertime to be as shown in FIG. 21. Using this, the daily electrical energy outputs of cells whose inclination angles θ against the horizontal plane were respectively 45°, 60°, 70° and 80° were calculated, and are shown in FIG. 22. In the regions of shallow sunlight incidence angle (regions of sunlight incidence angle θ to 45° and 135 to) 180°, inclining the cell had an adverse effect and resulted in an electrical energy output lower than that of a horizontal cell (cell angle=0°). However, as the sun moves to a high location, the effect of the inclined cell is exerted, thereby realizing a rapid increase of efficiency. That is, highly directional power generation characteristics are exhibited. The total electrical energy output obtained by integration of the daily electrical energy output is indicated in the table provided in FIG. 22. It was found that the total electrical energy output increased in accordance with the increase of the cell angle, and that at θ=80°, the total electrical energy output reached 1.28 times that of the horizontal cell (θ=0°).

### Example 2

In Example 2, there was prepared an organic photovoltaic cell characterized in that the solar cell had a concertina structure including a plurality of strip-shaped inclined surfaces. As the cell substrate, use was made of a 150 μm-thick film of PEN (polyethylene naphthalate) provided with a pattern obtained by etching a 150 nm-thick ITO in the shape of an electrode. This film was produced using a sputtering technique and an etching technique. Further, the ITO was provided with a 0.2 mm-wide auxiliary wiring of 2 nm molybdenum layer and 50 nm aluminum layer by a vapor deposition technique to thereby lower the apparent resistance of the ITO. This prevented any voltage drop. The resultant substrate was wound around a roll and set on an unwinding machine.

While continuously feeding the substrate to a printing section by the rotation of the unwinding machine, a hole transport layer, a active layer and an electron transport layer were sequentially applied thereonto by coating, and a film of negative electrode was formed by a vapor deposition technique. Just before the application of the hole transport layer, the film surface was cleaned using a UV cleaning machine, thereby removing foreign matter from the surface and increasing the hydrophilicity of the surface. Coating of each of the layers was performed in accordance with the electrode pattern by a gravure.offset technique.

An aqueous solution of PEDOT/PSS (poly(3,4-ethylenedioxythiophene)-poly(styrene sulfonate) [trade name Clevios PH] produced by Stark GmbH) for forming the hole transport layer was formed into a 60 nm-thick layer (thickness being one after drying). The drying was performed in a blower capable of sending a 110° C. hot air.

The preparation of organic semiconductor solid contents contained in the active layer was carried out in the following manner. Ten (10) parts by weight of PCDTBT (poly[N-9″-hepatadecanyl-2,7-carbazole-alt-5,5-(4′,7′-di-2-thienyl-2′,1′,3′-benzothiazole)]) produced by 1-Material as a p-type organic semiconductor and 40 parts by weight of 70PCBM ([6,6]-phenylC71 butyric methyl ester) produced by SOLENNE as an n-type organic semiconductor were mixed together. Subsequently, 1 ml of orthodichlorobenzene as a solvent and 35 mg of above solid contents were placed in a sample bottle, and irradiated with ultrasonic waves at 50° C. for two hours in an ultrasonic washer (model US-2, manufactured by Iuchi Seieido Co., Ltd.), thereby dissolving the solid contents in the solvent. Thus, a coating solution for forming the active layer was obtained. The coating solution was printed on the hole transport layer in a thickness of 89 nm. The drying was performed in a blower capable of sending a 70° C. hot air.

An amorphous titanium oxide layer as the electron transport layer was prepared by forming a solution produced by a sol gel method into a film. The titanium oxide solution was produced through the following operation. Namely, 5 ml of titanium isopropoxide, 25 ml of 2-methoxyethanol and 2.5 ml of ethanolamine were placed in a nitrogen-flushed 50 ml three-necked flask (equipped with stirring means, a reflux device and temperature adjusting means) and refluxed at 80° C. for two hours and at 120° C. for an hour. The thus obtained titanium oxide precursor solution was diluted 150-fold with IPA. The resultant solution was applied onto the active layer in a thickness of 20 nm by coating, thereby forming the electron transport layer. The drying was performed in a blower capable of sending a 80° C. hot air.

After the completion of the printing, the layers-provided substrate was cut into 30 centimeters, and the film of negative electrode was formed thereon by means of a vacuum vapor deposition apparatus. An 80 nm-thick aluminum layer was formed by performing resistance heating of an Al wire rod and vapor deposition through a mask for providing the shape of an electrode.

Further, as a passivation layer, silicon oxide was formed into a 82 nm-thick film by a sputtering technique. Although not shown in FIG. 14, wiring was designed so that divided cells were parallelly connected to each other.

Bending Operation:

The cell had a structure shaped like strips divided by every inclined side (divided cells). In order to facilitate bending, thin incisions were made by a cutter at the bend line portions of the cell (see FIG. 14A) prepared by the above process alternately on the obverse and reverse sides thereof. The cell was not formed at the portions destined to be ridge and valley bottom lines after bending. The reason therefor is that the device structure of the portions is damaged by bending, and design had been made so as to avoid the formation of the device at the portions.

Thereafter, referring to FIG. 14B, the incised portions were matched with the peaks of a metal mold shaped like triangular waves, and pressure was applied from upside and downside. Thus, the substrate was bent at the incised portions, thereby obtaining a multislope cell with concertina configuration as shown in FIG. 14C. The cell of 70° angle θ was obtained by using a metal mold 60 capable of realizing a bending angle of 70°. After the bending, the height from groove portion to top portion was 5 mm.

Fabrication of Module:

An acrylic plate provided with a cell fixing groove was disposed on a polycarbonate resin base board. Two cells each processed into a concertina structure (see FIG. 14C) were lined up, arranged so that the cell fixing groove matched the groove portions of the cells, and fixed together.

Thereafter, the cell electrodes were series-connected by means of an interconnector. The interconnector was wired by applying a silver paste by means of a dispenser. As the silver paste, use was made of D500 produced by Fujikura Kasei Co., Ltd. Although not shown, for outside drawing of the electrodes, the wiring between the cells and a terminal box was effected using a copper wire. The bonding between the cells and the copper wire was effected using the above silver paste. Finally, the cells were incorporated in a polycarbonate transparent protective plate, and fixed using an aluminum frame. Thus, a module was completed.

Practical multislope cell can be mass manufactured at a low cost by the method for manufacturing the solar cell with the use of a printing technique and a bending technique.

### Example 3

An organic photovoltaic cell was prepared in the same manner as in Example 1 except that the substrate film was provided on its surface with an antireflection film.

As the antireflection film, use was made of a titanium oxide antireflection film available from Sustainable Technology.

The power conversion efficiency of the thus obtained organic photovoltaic cell was measured. It was found that the power conversion efficiency was about 5% higher than in Example 1. The measurement was performed in the same manner as in Test 1 of Example 1.

According to the foregoing Embodiments and Examples, the organic photovoltaic cell capable of realizing high power conversion efficiency and low manufacturing cost and the method for manufacturing the same can be provided by inclining the solar cell.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. An organic photovoltaic cell comprising:
a substrate of a corrugated structure having a plurality of inclined surfaces alternately inclined in opposite directions, each of the inclined surfaces of the substrate being inclined at 60 to 89° against a horizontal plane;
a plurality of solar cells formed on at least a part of the plurality of inclined surfaces of the substrate, each of the solar cells comprising a pair of electrodes and a bulk heterojunction active layer interposed between the electrodes, the active layer containing a p-type organic semiconductor and an n-type organic semiconductor,
a support plate supporting ridge line portions of groove portions of the substrate; and
a transparent protective plate provided on ridge line portions of top portions of the substrate.

2. The organic photovoltaic cell according to claim 1, wherein at least one of the support plate and the transparent protective plate has fixing grooves configured to fix the ridge line portions of the substrate.

3. The organic photovoltaic cell according to claim 1, wherein the plurality of solar cells are connected by means of an interconnector.

4. The organic photovoltaic cell according to claim 1, wherein the plurality of inclined surfaces define a height from the groove portion to the top portion of 1 mm to 20 cm.

5. The organic photovoltaic cell according to claim 1, wherein the solar cell is provided on its light incident face with an antireflection film.

6. The organic photovoltaic cell according to claim 1, wherein the substrate comprises a flexible material so that the plurality of inclined surfaces alternately inclined in opposite directions are formed by bending the substrate.
